(19) United States
(12) Patent Application Publication
(10) Pub. No.: US 2020/0234920 A1
(43) Pub. Date: Jul. 23, 2020

(54) COIL AND WINDOW FOR PLASMA PROCESSING SYSTEM

(71) Applicant: Lam Research Corporation, Fremont, CA (US)

(72) Inventors: Shen PENG, Dublin, CA (US); Dan MAROHL, San Jose, CA (US); Ambarish CHHATRE, Danville, CA (US); Ming-Te LIN, Danville, CA (US); Andras KUTHI, Thousand Oaks, CA (US)

(21) Appl. No.: 16/253,948

(22) Filed: Jan. 22, 2019

(51) Int. Cl. H01J 37/32; H01L 21/67

(52) U.S. Cl. CPC H01J 37/32119; H01L 21/67069; H01J 37/3211; H01J 2237/3344; H01J 37/32513; H01J 37/3244; H01J 37/32183

(57) ABSTRACT

An apparatus for processing substrates is provided. A plasma processing chamber is provided. At least one substrate support for supporting at least one substrate is in the plasma processing chamber. At least one gas inlet is provided for flowing gas into the plasma processing chamber. A dielectric window forms a cover for the plasma processing chamber. The dielectric window comprises an outer dielectric window ring with a central aperture and an inner concaved dielectric window extending across the central aperture, wherein the inner concaved dielectric window forms a volume in fluid communication with an interior of the plasma processing chamber, and wherein the at least one gas inlet flows gas into the volume of the inner concaved dielectric window. An outer coil assembly is adjacent to the outer dielectric window ring. An inner coil assembly surrounds the inner concaved dielectric window.

### BACKGROUND

The disclosure relates to an apparatus for forming semiconductor devices on a semiconductor wafer. More specifically, the disclosure relates to an inductive apparatus for forming semiconductor devices.

In forming semiconductor devices, semiconductor device systems may use inductive coupling to provide power to a plasma.

### SUMMARY

To achieve the foregoing and in accordance with the purpose of the present disclosure, an apparatus for processing substrates is provided. A plasma processing chamber is provided. At least one substrate support for supporting at least one substrate is in the plasma processing chamber. At least one gas inlet is provided for flowing gas into the plasma processing chamber. A dielectric window forms a cover for the plasma processing chamber. The dielectric window comprises an outer dielectric window ring with a central aperture and an inner concaved dielectric window extending across the central aperture, wherein the inner concaved dielectric window forms a volume in fluid communication with an interior of the plasma processing chamber, and wherein the at least one gas inlet flows gas into the volume of the inner concaved dielectric window. An outer coil assembly is adjacent to the outer dielectric window ring. An inner coil assembly surrounds the inner concaved dielectric window.

These and other features of the present disclosure will be described in more details below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic cross-sectional side view of a plasma processing chamber that may be used in an embodiment.

FIG. 2 is a computer system that may be used in an embodiment.

### DETAILED DESCRIPTION OF THE EMBODIMENTS

The present disclosure will now be described in detail with reference to a few exemplary embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

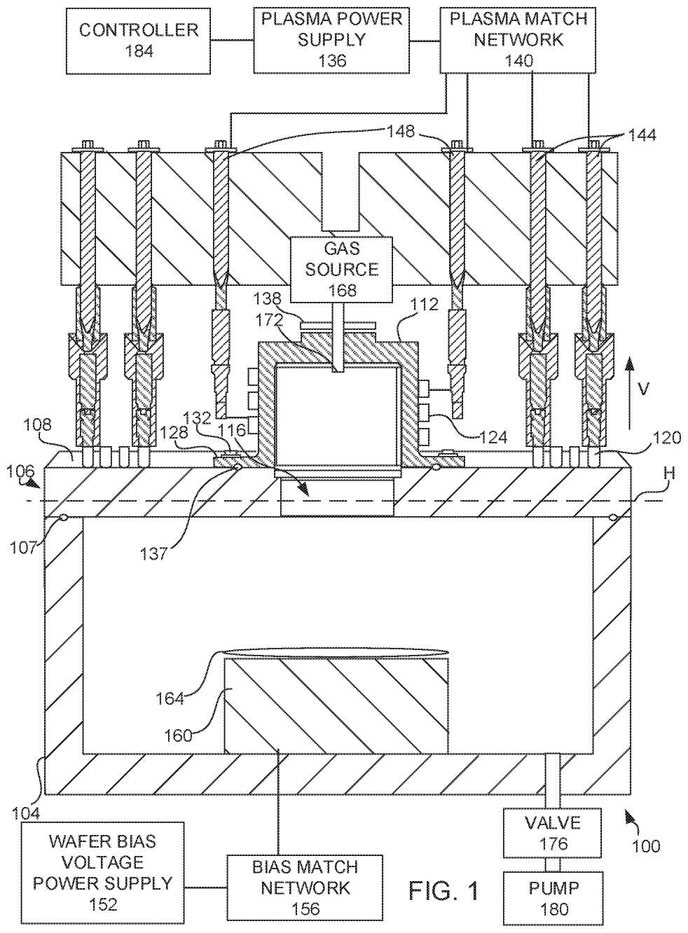

In an exemplary embodiment, FIG. 1 is a cross-sectional side view of plasma processing chamber 100 that may be used in an embodiment. The plasma processing chamber 100 comprises a chamber bottom 104 and a power window 106 covering an opening in the chamber bottom 104. An O-ring 107 may be provided to be a chamber sealing member to create a seal between the chamber bottom 104 and the power window 106. The power window 106 comprises an outer dielectric window ring 108 and an inner concaved dielectric window 112. The outer dielectric window ring 108 extends across the opening in the chamber bottom 104. The outer dielectric window ring 108 has a central aperture 116. The inner concaved dielectric window 112 extends across the central aperture 116. The inner concaved dielectric window 112 forms a volume. The volume of the inner concaved dielectric window 112 is in fluid communication with the interior of the plasma processing chamber 100 through the central aperture 116. The inner concaved dielectric window 112 comprises sidewalls extending around the central aperture 116. A flange 128 and bolts 132 are used to connect the sidewalls of the inner concaved dielectric window 112 to the outer dielectric window ring 108. A window O-ring 137 is a sealing member used to create a seal between the outer dielectric window ring 108 and the inner concaved dielectric window 112. A disk shaped magnet 138 may be placed on top of the inner concaved dielectric window 112.

A wafer bias voltage power supply 152 tuned by a bias match network 156 provides power to an electrode 160 to set the bias voltage on a substrate 164. The electrode 160 is used as a chuck to support the substrate 164.

In this embodiment, the outer dielectric window ring 108 is flat. A horizontal plane H extends through the edges and central aperture 116 of the outer dielectric window ring 108. A vertical height V is perpendicular to the horizontal plane H. In this embodiment, the volume of the inner concaved dielectric window 112 has a depth along the direction of the vertical height V. The depth of the volume of the inner concaved dielectric window 112 extends from a first end of the inner concaved dielectric window 112 adjacent to the outer dielectric window ring 108 to a second end of the inner concaved dielectric window 112 furthest from the outer dielectric window ring 108. The central aperture 116 has a width along the direction of the horizontal plane H. In this embodiment, the depth of the volume of the inner concaved dielectric window 112 is at least half the width of the central aperture 116, so that the ratio of the depth of the inner concaved dielectric window 112 to the width of the central aperture 116 is at least 1:2. In this embodiment, the sidewalls and the outer dielectric ring form a 90°.

A transformer coupled power (TCP) assembly comprises one or more TCP coils. In this embodiment, the TCP assembly comprises an outer coil assembly 120, adjacent to the outer dielectric window ring 108, and an inner coil assembly 124 adjacent to the inner concaved dielectric window 112. In this embodiment, a plane passing through each winding of the outer coil assembly 120 is parallel to the horizontal plane H. In this embodiment, the outer coil assembly 120 is flat. The outer coil assembly 120 comprises at least three windings. The inner coil assembly 124 comprises at least three windings. The sequential windings of the inner coil assembly 124 extend along the depth of the inner concaved dielectric window 112, so that each winding defines a plane, wherein each defined plane is at a different location along the depth of the inner concaved dielectric window 112. The inner coil assembly 124 may form a coil so that each winding defines a plane so that subsequent windings define a plane spaced either continuously further from or continuously near to the substrate 164 than planes defined by previous windings. In this example, the outer coil assembly 120 has an inner aperture with an inner diameter. The inner coil assembly 124 has an outer diameter. The outer diameter of the inner coil assembly 124 is less than the inner diameter of the inner aperture of the outer coil assembly 120. The inner coil assembly 124 is placed above the inner aperture of the outer coil assembly 120.

A plasma power supply 136, tuned by a plasma match network 140, supplies power to the TCP assembly. A set of outer coil assembly radio frequency (RF) rods 144 provide an electrical connection between the plasma match network 140 and the outer coil assembly 120. A set of inner coil assembly RF rods 148 provide an electrical connection between the plasma match network 140 and the inner coil assembly 124. The plasma match network 140 is able to supply different and independent amounts of RF power to the set of outer coil assembly RF rods 144 and inner coil assembly RF rods 148. The ability to provide different RF powers to the set of outer coil assembly RF rods 144 and inner coil assembly RF rods 148 allows for different induction powers to be provided by the outer coil assembly 120 and the inner coil assembly 124 to allow a more uniform process across a substrate surface.

The outer dielectric window ring 108 and the inner concaved dielectric window 112 are provided to separate the outer coil assembly 120 and inner coil assembly 124 from the interior of the plasma processing chamber 100 while allowing energy to pass from the outer coil assembly 120 and the inner coil assembly 124 into the plasma processing chamber 100.

The plasma power supply 136 and the wafer bias voltage power supply 152 may be configured to operate at specific radio frequencies such as, for example, 13.56 megahertz (MHz), 27 MHz, 2 MHz, 60 MHz, 200 kilohertz (kHz), 2.54 gigahertz (GHz), 400 kHz, and 1 MHz, or combinations thereof. Plasma power supply 136 and wafer bias voltage power supply 152 may be appropriately sized to supply a range of powers in order to achieve desired process performance. For example, in one embodiment, the plasma power supply 136 may supply the power in a range of 50 to 5000 Watts, and the wafer bias voltage power supply 152 may supply a bias voltage in a range of 20 to 2000 volts (V). For a bias voltage up to 4 kilovolts (kV) or 5 kV, a power of no more than 25 kilowatts (kW) is provided. In addition, each of the outer coil assembly 120 and the inner coil assembly 124 may be comprised of two or more sub-coils, which may be powered by a single power supply or powered by multiple power supplies.

A gas source/gas supply mechanism 168 is in fluid connection with the interior of the plasma processing chamber 100 through a gas inlet 172. The gas inlet 172 provides gas into an end of the volume of the inner concaved dielectric window 112 spaced furthest from the substrate 164. The process gases and by-products are removed from the plasma process chamber 100 via a pressure control valve 176 and a turbo molecular pump 180, which also serve to maintain a particular pressure within the plasma processing chamber 100. A controller 184 sets points for the plasma power supply 136, gas source/gas supply mechanism 168, and the wafer bias voltage power supply 152. A Syndion® tool made by Lam Research Corp. of Fremont, Calif., may be used to practice an embodiment.

In operation, the substrate 164 may pass into the plasma processing chamber 100 through a substrate port. The gas source 168 may provide a process gas, such as an etch gas, through the gas inlet 172 into the end of the volume of the inner concaved dielectric window 112 spaced furthest from the substrate 164. In this embodiment, the etch gas is used for a deep silicon etch of the substrate 164. The plasma power supply 136 provides RF power through the plasma match network 140 to the set of outer coil assembly RF rods 144 and inner coil assembly RF rods 148. Power from the outer coil assembly RF rods 144 passes to the outer coil assembly 120. Power from the inner coil assembly RF rods 148 passes to the inner coil assembly 124. The inner coil assembly 124 excites and forms the process gas into a plasma. The placement of the sequential windings of the inner coil assembly 124 along the depth of the inner concaved dielectric window 112 causes ions in the plasma to be accelerated towards the substrate 164 in the plasma processing chamber 100. The accelerated plasma enters the interior of the chamber bottom 104. The outer coil assembly 120 provides RF power to maintain the plasma in the chamber bottom 104. By tuning power ratios between the outer coil assembly 120 and the inner coil assembly 124 radial processing of the substrate 164 may be made more uniform. In addition, higher power may be provided with the improved uniformity. The higher power allows for a faster etch process. Features with height to width aspect ratios of greater than 50:1 are etched into silicon. A deposition and etch process may be used to reduce taper and bowing in the etched features. A faster etch rate is important when etching high aspect ratio features. Various embodiments have found an increase in etch rate of at least three times.

An example of a silicon substrate etch may flow an etch gas of 100 standard cubic centimeters per minute (sccm) sulfur hexafluoride (SF₆) from the gas source supply mechanism 168 into the plasma processing chamber 100. Pressure in the plasma processing chamber 100 is maintained at about 100 milliTorr. The plasma power supply 136 provides power to the outer coil assembly 120 and the inner coil assembly 124. The outer coil assembly 120 and the inner coil assembly 124 provide 500 to 5500 watts of power to transform the etch gas into a plasma.

In various embodiments, the cross-sectional area of the inner concaved dielectric window 112 is less than the cross-sectional area of the outer dielectric window ring 108. In other embodiments, the outer dielectric window ring 108 and the inner concaved dielectric window 112 form a single piece. In other embodiments, sidewalls of the inner concaved dielectric window 112 are tapered forming a frusto-conical shape. In such embodiments, the inner coil assembly 124 may also be in a frusto-conical shape. The taper may also improve radial uniformity of the processed substrate 164. In various embodiments the sidewalls of the inner concaved dielectric window 112 make an outer angle on the outside of the sidewalls between 90° (vertical side walls) to 150° with the outer dielectric window ring 108. In various embodiments, the diameter of the inner concaved dielectric window 112 is less than half of the outer diameter of the outer dielectric window ring. In other embodiments, the diameter of the inner concaved dielectric window 112 is less than one third and greater than one fifth of the outer diameter of the outer dielectric window ring.

In various embodiments, at least one plasma power supply is electrically connected to at least one plasma match network electrically connected to the outer coil assembly and inner coil assembly. Such embodiments may have at least a first plasma power supply electrically connected to at least a first plasma match network electrically connected to the outer coil assembly and at least a second plasma power supply electrically connected to at least a second plasma match network electrically connected to the inner coil assembly.

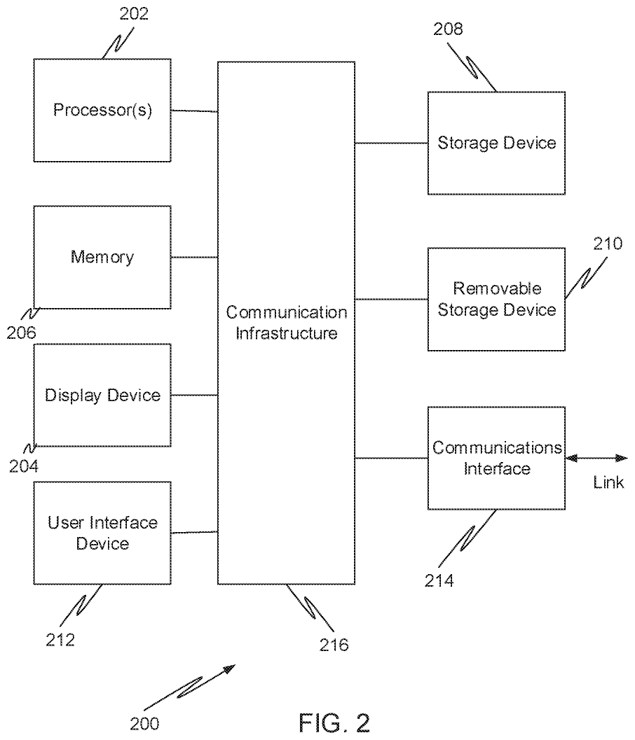

FIG. 2 is a high-level block diagram showing a computer system 200, which is suitable for implementing a controller 184 used in embodiments. The computer system may have many physical forms ranging from an integrated circuit, a printed circuit board, and a small handheld device, up to a huge super computer. The computer system 200 includes one or more processors 202, and further can include an electronic display device 204 (for displaying graphics, text, and other data), a main memory 206 (e.g., random access memory (RAM)), storage device 208 (e.g., hard disk drive), removable storage device 210 (e.g., optical disk drive), user interface devices 212 (e.g., keyboards, touch screens, keypads, mice or other pointing devices, etc.), and a communication interface 214 (e.g., wireless network interface). The communication interface 214 allows software and data to be transferred between the computer system 200 and external devices via a link. The system may also include a communications infrastructure 216 (e.g., a communications bus, cross-over bar, or network) to which the aforementioned devices/modules are connected.

Information transferred via communications interface 214 may be in the form of signals such as electronic, electromagnetic, optical, or other signals capable of being received by communications interface 214, via a communication link that carries signals and may be implemented using wire or cable, fiber optics, a phone line, a cellular phone link, a radio frequency link, and/or other communication channels. With such a communications interface, it is contemplated that the one or more processors 202 might receive information from a network, or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that is executed by a computer using an interpreter. Computer readable media may also be computer code transmitted by a computer data signal embodied in a carrier wave and representing a sequence of instructions that are executable by a processor.

While this disclosure has been described in terms of several exemplary embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An apparatus for processing substrates, comprising:
a plasma processing chamber;
at least one substrate support for supporting at least one substrate in the plasma processing chamber;
at least one gas inlet for flowing gas into the plasma processing chamber;
a dielectric window forming a cover for the plasma processing chamber; comprising:
an outer dielectric window ring with a central aperture; and
an inner concaved dielectric window extending across the central aperture,
wherein the inner concaved dielectric window forms a volume in fluid communication with an interior of the plasma processing chamber, and wherein the at least one gas inlet flows gas into the volume of the inner concaved dielectric window;
an outer coil assembly adjacent to the outer dielectric window ring; and
an inner coil assembly surrounding the inner concaved dielectric window.

2. The apparatus, as recited in claim 1, wherein the inner concaved dielectric window has a first end adjacent to the outer dielectric window ring and the interior of the plasma processing chamber and a second end spaced furthest from the outer dielectric window ring, wherein a depth extends from the first end to the second end, wherein the inner coil assembly extends along the depth of the inner concaved dielectric window.

3. The apparatus, as recited in claim 1, wherein the outer dielectric window ring is flat with edges defining a horizontal plane extending through the edges, and wherein the inner concaved dielectric window has a depth perpendicular to the horizontal plane, and wherein the central aperture has a width, wherein a ratio of the depth of the inner concaved dielectric window to the width of the central aperture is at least 1:2.

4. The apparatus, as recited in claim 3, wherein the inner coil assembly comprises at least three windings, wherein each winding of the at least three windings defines a plane, wherein each defined plane of the at least three windings are at different locations along the depth of the inner concaved dielectric window.

5. The apparatus, as recited in claim 1, wherein the inner concaved dielectric window comprises sidewalls extending around the central aperture and connected to the outer dielectric window ring.

6. The apparatus, as recited in claim 5, wherein the sidewalls of the inner concaved dielectric window and the outer dielectric window ring form an outer angle in a range of 90° to 150°.

7. The apparatus, as recited in claim 1, wherein the inner concaved dielectric window has a first end adjacent to the outer dielectric window ring and the interior of the plasma processing chamber and a second end spaced furthest from the outer dielectric window ring, further comprising a magnet adjacent to the second end of the inner concaved dielectric window.

8. The apparatus, as recited in claim 1, wherein the inner concaved dielectric window has a first end adjacent to the outer dielectric window ring and the interior of the plasma processing chamber and a second end spaced furthest from the outer dielectric window ring, wherein the at least one gas inlet for flowing gas into the plasma processing chamber flows the gas into the interior of the plasma processing chamber at the second end of the inner concaved dielectric window.

9. The apparatus, as recited in claim 1, further comprising a power supply, wherein the power supply is able to provide independent amounts of power to the inner coil assembly and the outer coil assembly.

10. The apparatus, as recited in claim 1, wherein the outer dielectric window ring is a ring and wherein the inner concaved dielectric window is separate from the outer dielectric window ring, further comprising a sealing member for creating a seal between the outer dielectric window ring and the inner concaved dielectric window.

11. The apparatus, as recited in claim 10, wherein the plasma processing chamber comprises a chamber bottom with an opening, wherein the outer dielectric window ring spans across the opening of the chamber bottom, and further comprising a chamber sealing member for creating a seal between the chamber bottom and the outer dielectric window ring.

12. The apparatus, as recited in claim 1, wherein the plasma processing chamber comprises a chamber bottom with an opening, wherein the outer dielectric window ring spans across the opening of the chamber bottom, and further comprising a chamber sealing member for creating a seal between the chamber bottom and the outer dielectric window ring.

13. The apparatus, as recited in claim 1, further comprising at least one plasma power supply electrically connected to the outer coil assembly and the inner coil assembly.

14. The apparatus, as recited in claim 13, further comprising at least one plasma match network electrically connected between the at least one plasma power supply and the outer coil assembly and inner coil assembly.

15. The apparatus, as recited in claim 14, further comprising a controller controllably connected to the at least one plasma power supply.

16. The apparatus, as recited in claim 15, wherein the controller, comprises:
at least one processor; and
computer readable media, comprising:
computer code for providing a first power to the outer coil assembly; and
computer code for providing a second power to the inner coil assembly, wherein the first power is different than the second power.

17. The apparatus, as recited in claim 16, wherein a difference between the first power and the second power provides a uniform process across at least one substrate.
